(19) United States
(12) Patent Application Publication
(10) Pub. No.: US 2002/0130694 A1
(43) Pub. Date: Sep. 19, 2002

(54) Self-generating oscillator field of the invention

(76) Inventor: Henry Fang, Yilan Hsien (TW)

Correspondence Address: J.C. Patents, 4 Venture, Suite 250, Irvine, CA, 92618, US

(21) Appl. No.: 09/971,486

(22) Filed: Oct. 4, 2001

Related U.S. Application Data
(62) Division of application No. 09/811,253, filed on Mar. 16, 2001, now abandoned.

(51) Int. Cl. H03H 11/26

(52) U.S. Cl. 327/277

(57) ABSTRACT

The invention comprises a device that internally self-generates a clock signal, and provides methods for adjusting the clock signal through the use of a reference frequency. The device is composed of a plurality of propagation delay devices. The propagation devices can be individually selected as to allow a signal to propagate through them, or to not allow a signal to pass. The device creates a clock signal by setting a logical condition at the start of the propagation devices, allowing a signal to pass through, and then changing the inputted logical condition. The time it takes to pass through the devices depends on the number of devices selected. Therefore with the changing of the logical conditions at the output of the device a clock signal can be created. To determine the frequency of the output signal, the output is compared to a known frequency of a reference signal which can originate from an inexpensive external crystal oscillator. The number of generated clock signals is counted in one clock cycle of the reference signal. The device then calculates the generated clock signal frequency and can change the frequency if necessary. The invention also discloses a clock divider for further adjusting the generated clock signal.

### BACKGROUND OF INVENTION

1. Field of the Invention

The present invention relates to an internal clock generator, and more particularly, to an internal clock generator that is self-generating, and adjustable.

2. Description of Related Art

Many electronic devices require oscillating signals or clock signals, for timing procedures, and to achieve synchronization within a device. As electronic devices become more complex there has arisen a need for a low-cost clock signal generating device that can be used in low-cost electronic devices. Most current electronic devices utilize a Phase Lock Loop or an Inverter Loop to generate internal clock signals.

As well known in the art a Phase Lock Loop (PLL) consists of a phase comparator, a loop filter, and a voltage control oscillator (VCO). A base clock and reference clock are supplied to the PLL. The phase comparator compares the phase of the base clock with the phase of the reference clock, and outputs a signal indicating the phase difference between the base clock, and the reference clock. The loop filter eliminates a high-frequency component from the signal. The voltage control oscillator outputs a frequency-variable clock in correspondence with the signal output from the loop filter. Thus, the VCO clock has an oscillating frequency that corresponds to the outputted signal from the PLL. There are many disadvantages to a Phase Lock Loop design. The PLL can take time to lock onto a signal, it is very susceptible to noise, limited in the range of frequencies in which it can operate, has high power consumption, has a complex design, and is expensive to build.

Many designs also make use of inverter loops to create internal clock signals. An inverter loop comprises a plurality of inverters having an input connected to an output. The inverter loop has an input external clock and provides a series of clock signals that are shifted in phase. This allows for the creation of an internal clock signal with a higher frequency. The inverter loop has the disadvantages of a non-precise frequency, and frequency range limitation.

In addition both the PLL and the Inverter loop require a high frequency external frequency generators. These devices are expensive, and add to high frequency stress on a printed circuit board.

Therefore there exists a need for a low cost internal clock generator that has a wide frequency range, precise frequency control, low power consumption, and does not require an expensive high frequency clock generator.

### SUMMARY OF THE INVENTION

The invention comprises a device that internally self-generates a clock signal, and can adjust the clock signal through the use of a reference frequency.

The device is composed of a plurality of propagation delay devices which in one embodiment can be multiplexers. The multiplexers can be individually selected as to allow a signal to propagate through them, or to not allow a signal to pass. The device creates a clock signal by setting a logical condition at the start of the propagation devices. The signal then passes through the propagation devices. The time it takes to pass through the devices depends on the number of devices selected. After the signal passes through the devices the logical condition at the input alternates, and the process starts over again. Therefore with the changing of the logical conditions at the output of the device a clock signal can be created. By varying the number of propagation delay devices used in the clock generator, the clock signal frequency can be varied.

To determine the frequency of the output signal, the output is compared to a reference signal which can originate from an inexpensive external crystal oscillator. The frequency of the inputted reference frequency is known. The number of generated clock signals is counted in one clock cycle of the reference signal. The device then calculates the generated clock signal frequency and can change the frequency if necessary. The invention also discloses a clock divider for further adjusting the generated clock signal.

Therefore this device solves many of the prior arts problems by providing a low cost, variable frequency device that does not require an expensive high frequency clock generator.

These and other features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there is described exemplary embodiments of the invention.

### BRIEF DESCRIPTION OF DRAWINGS

FIG. 1 shows a device according to one embodiment of the invention for clock generation.

FIG. 2 is a flowchart showing the process for adjusting a generated clock signal frequency.

FIG. 3 is a diagram showing a method for adjusting the generated clock signal frequency.

FIG. 4 shows a device according to one embodiment of the invention of a clock trigger.

FIG. 5 shows a timing diagram for the counting the clock cycles of generated clock.

FIG. 6 shows a complete device according to one embodiment of the invention of a clock generator and adjusting method.

### DETAILED DESCRIPTION

In the following detailed description of the preferred embodiments, reference is made to the accompanying drawings which form a part hereof, and in which is shown by way of illustration specific preferred embodiments in which the invention may be practiced. the preferred embodiments are described in sufficient detail to enable these skilled in the art to practice the invention, and it is to be understood that other embodiments may be utilized and that logical, changes may be made without departing from the spirit and scope of the present invention. The following detailed description is, therefore, not to be taken in a limiting sense, and the scope of the present invention is defined only be the appended claims.

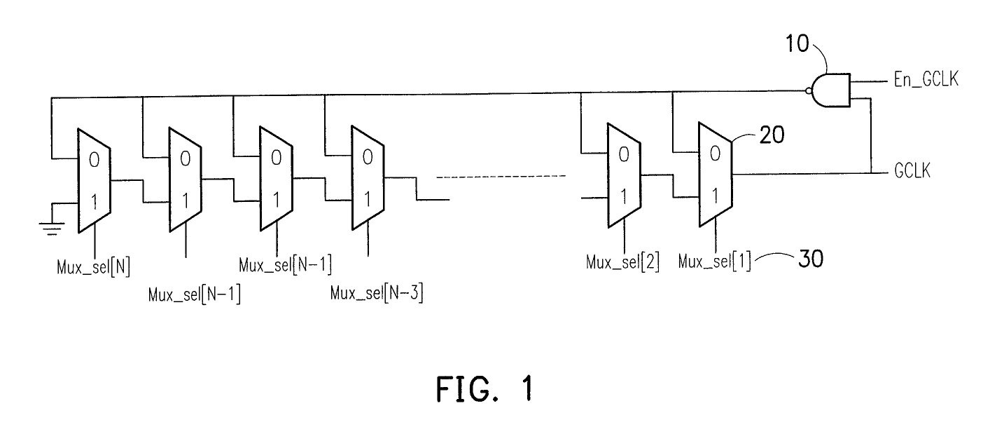

FIG. 1 shows a clock generating circuit according to one embodiment of the apparatus. The circuit uses a propagation delay of a gate to create a clock signal. If several gates are connected together than the propagation delay will be the sum of the total gate propagation delays. In the preferred embodiment of the invention multiplexers 20 are used for a propagation delay, but one skilled in the art could make use of any device that has a propagation delay. Each multiplexer 20 can be individually activated or non-activated through logical addressing 30. However a person skilled in the art will recognize that addressing for activation can occur in a variety of methods including using a processor, switches, latches, registers, etc.

Referring back to FIG. 1 the diagram shows an example of a device that is composed of a plurality of addressable multiplexers (MUX) 20, and a NAND 10. One input of the NAND 10 is connected to the output from the multiplexers 20. The output of the NAND 10 is connected to the input of the multiplexers 20. An enable signal En_GCLK connected to an input of the NAND 10, and can activate or deactivate the clock generator. In the diagram we will assume that the propagation delay of each MUX 20 is D_{MUX}, and the propagation delay of a NAND 10 is D_{NAND}. If we set Mux_sel[N:1] as x7FFFh (propagate 16 MUXs and 1 NAND gate), we will have a clock signal with a halftime equal to 16*D_{MUX}+1*D_{NAND}. Therefore a clock signal is generated with a cycle time of 2*(16*D_{MUX}+1*D_{NAND}).

The propagation delay of a gate will be affected by process variations, operation temperature, voltage, wire loading etc. Therefore it is very difficult to calculate a desired frequency, so adjustment is necessary for precise clock frequency generation. For adjustment the invention uses a reference frequency. In a preferred embodiment the reference frequency is from an external crystal generator. Someone skilled in the art will recognize that any reference frequency can be used both from external sources, and from internal sources such as a processors own internal clock.

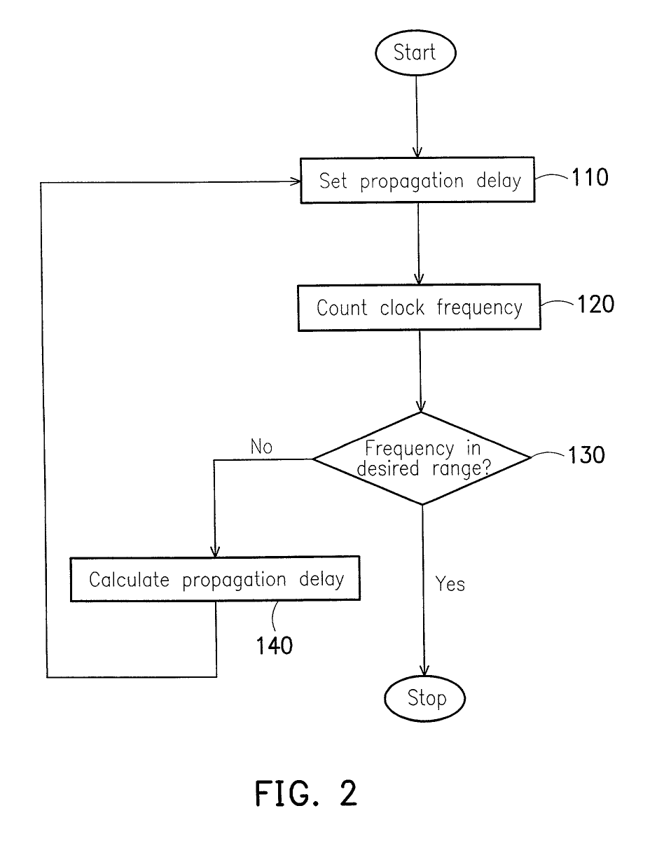

FIG. 2 shows a flowchart for adjusting the generated clock signal according to an external clock signal. The method first sets the propagation delay 110 by selecting a plurality of devices that correspond to a required delay. In step 120 the device counts how many cycles of a generated clock signal occur in a time period of a reference clock signal. The generated clock frequency can then be determined by multiplying the number of cycles in a reference clock by the frequency of the known reference frequency. In step 130 the device determines if the generated clock frequency is in a desired range. If the clock frequency falls within a desired range the program ends. If the clock signal does not fall within a desired range the program calculates what propagation delay devices are needed to achieve a clock signal within the range 150. The program then returns to step 110.

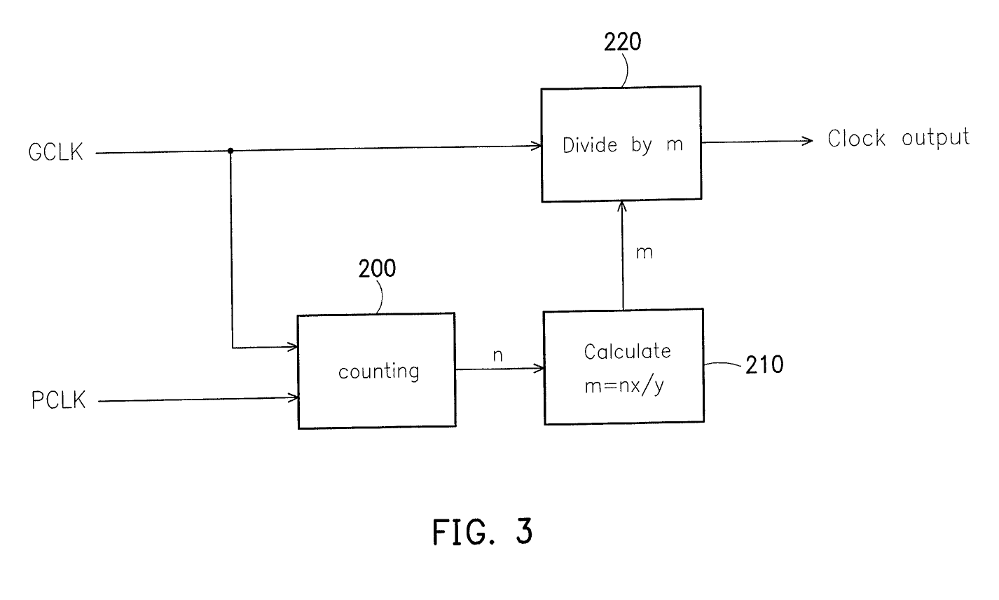

FIG. 3 shows another method for adjusting the generated clock which can be used for finer tuning in conjunction with the method as described above. A generated clock signal (GCLK), and a reference clock signal (PCLK) are inputted to a counter 200. The frequency of the reference clock signal (PCLK) is known to be [x]. The counter determines how many cycles of a generated clock signal occur in a time period of a reference clock signal which will be referred to as [n]. The frequency of the generated clock can then be determined. In step 210 a number to divide the generated clock signal [g], to obtain the desired frequency [y] is determined to be [m]. The divisor [m] is determined by the equation:

m=n*x/y

In step 220 the generated clock signal [g] is divided by [m] to obtain the desired clock output frequency [y]. Because the divider is integer-base, for a more precise clock output we have to change the propagation delay in order to achieve a [m] that is close to an integer.

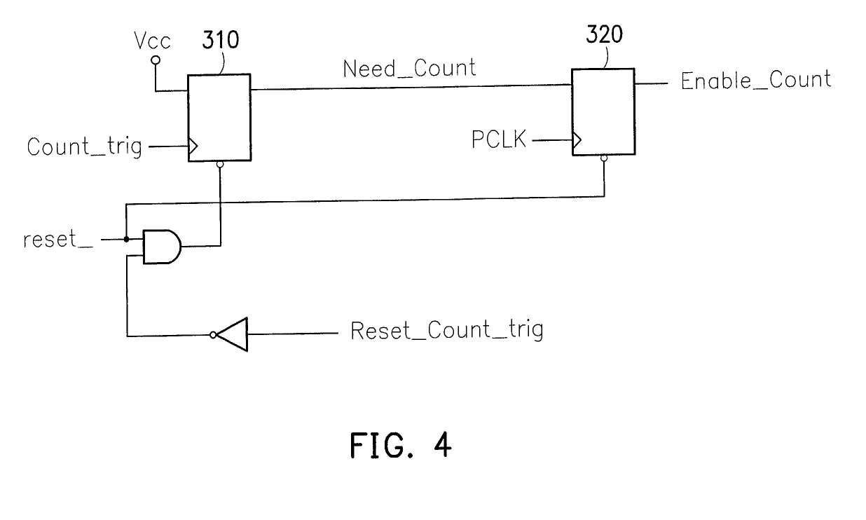

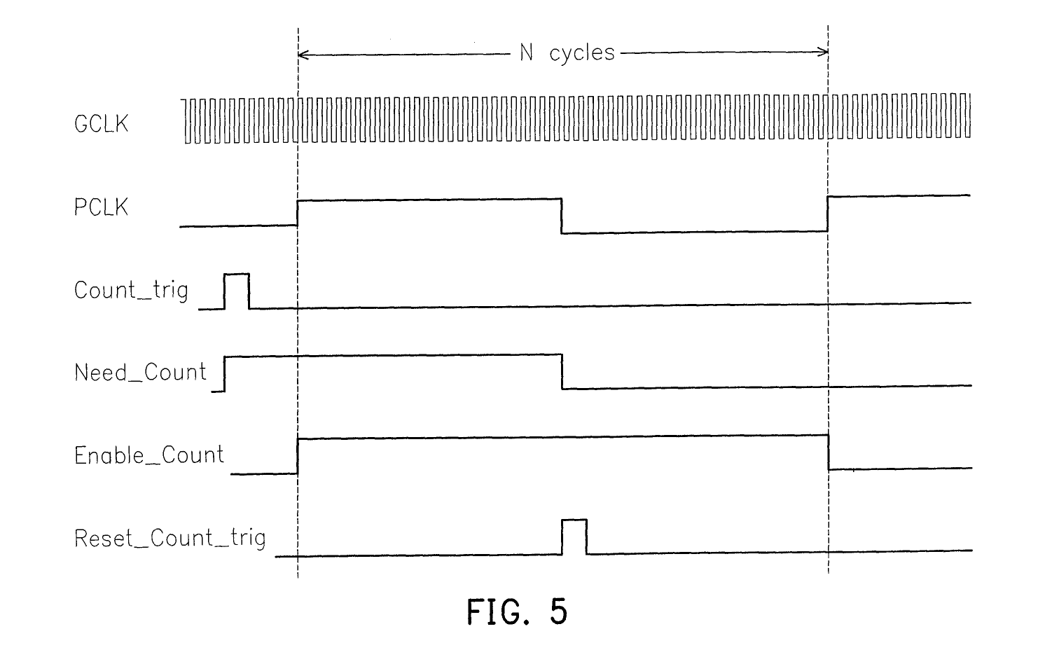

FIG. 4 shows an apparatus according to one preferred embodiment of the invention for triggering a count of the generated clock signal. Reference can be made to FIG. 5 to explain the relationship of the timing signals. When a Count_trig signal is inputted to device 310 it activates a Need_Count signal that is inputted to device 320. An AND gate connects to the enable of device 310. The AND gate is connected to two reset signals, reset_, and Reset_Count_trig. Reset_Count_trig is envisioned as an internal reset, while reset_can be an external reset. Device 320 activates an Enable_Count signal that corresponds to one clock signal period of PCLK. The enable of device 320 is connected to reset signal reset_. A Reset_Count_trig signal causes the Need_Count signal to go low therefore resetting the count trigger. FIG. 5 is a timing diagram that corresponds to the apparatus shown in FIG. 4.

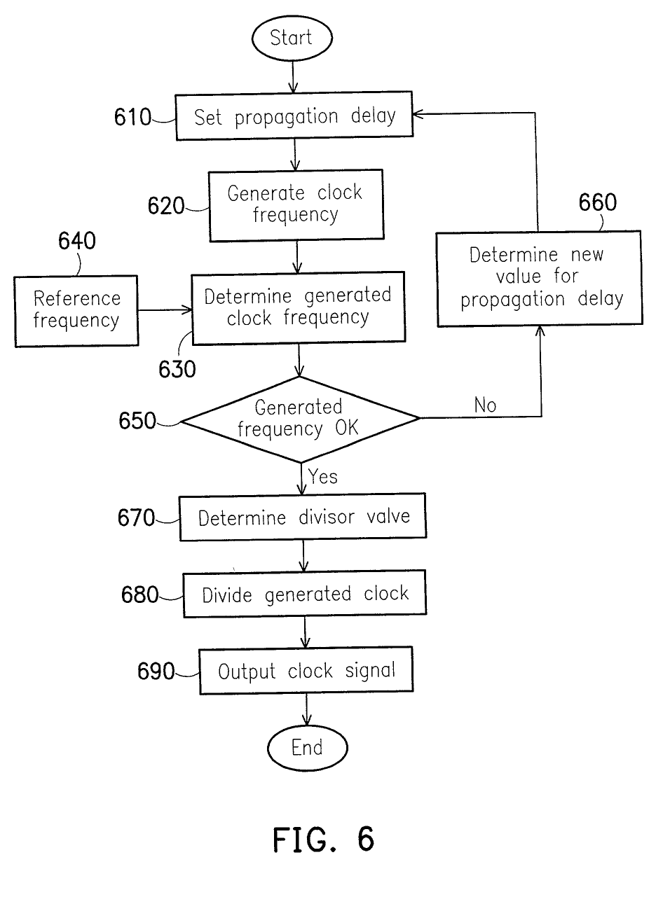

FIG. 6 shows all of the preceding elements combined into an envisioned device. In step 610 the propagation delay to generate the frequency of the clock signal is set. In step 620 the clock frequency is generated. In step 630 the frequency of the generated clock signal is determined by using reference frequency 640. In step 650 if the generated frequency is okay the program continues. If the generated frequency needs to be altered a new propagation delay is determined in step 660 and the program returns to step 610. In step 660 a divisor value is determined, and then the generated clock signal is divided according to that value in step 670. In step 680 the final clock signal is outputted.

Various additional modifications may be made to the illustrated embodiments without departing from the spirit and scope of the invention. Therefore, the invention lies in the claims hereinafter appended.

What is claimed:

1. An apparatus for generating a clock signal by using a propagation delay comprising a plurality of propagation delay devices composed in such a way as to alternate logical states.

2. The apparatus of claim 1, further composing a gate structure wherein an input is connected to the output of the apparatus and an output connected to an input of the apparatus.

3. The gate structure of claim 2, where the gate is an AND gate.

4. The gate structure of claim 2, wherein an input consists of an enable signal.

5. An apparatus for generating a clock signal by using a propagation delay comprising a plurality of propagation delay devices that are capable of being enabled or disabled, composed in such a way as to alternate logical states by using signal propagation delay.

6. The apparatus of claim 5, where the propagation delay devices are multiplexers.

7. The apparatus of claim 5, further comprising a gate structure wherein an input is connected to the output of the apparatus and an output connected to an input of the apparatus.

8. The gate structure of claim 7, where the gate is an AND gate.

9. The gate structure of claim 7, wherein an input consists of an enable signal.

10. An apparatus for generating and adjusting a clock signal by using a propagation delay comprising:
a plurality of propagation delay devices that are capable of being enabled or disabled composed in such a way as to alternate logical states;
a clock signal counter.

11. The apparatus of claim 10, where the propagation delay devices are multiplexers.

12. The apparatus of claim 10, further comprising a gate structure wherein an input is connected to the output of the apparatus and an output connected to an input of the apparatus.

13. The gate structure of claim 12, where the gate is an AND gate.

14. The gate structure of claim 12, wherein an input consists of an enable signal.

15. The clock signal counter of claim 10, which is further composed of a reference signal input.

16. The reference signal input of claim 15 which is an external crystal oscillator signal.

17. An apparatus for generating and adjusting a clock signal by using a propagation delay comprising:
a plurality of propagation delay devices that are capable of being enabled or disabled composed in such a way as to alternate logical states;
a clock divider;
a clock signal counter.

18. The apparatus of claim 17, where the propagation delay devices are multiplexers.

19. The apparatus of claim 17, further comprising a gate structure wherein an input is connected to the output of the apparatus and an output connected to an input of the apparatus.

20. The gate structure of claim 19, where the gate is an AND gate.

21. The gate structure of claim 19, wherein an input consists of an enable signal.

22. The clock signal counter of claim 17, which is further composed of a reference signal input

23. The reference signal input of claim 22, which is an external crystal oscillator signal.

24. A method for generating a clock signal comprised of:
calculating a propagation delay;
selecting a plurality of propagation delay devices.

25. The method of claim 24, wherein the calculated propagation delay equals the propagation delay through the selected devices.

26. The method of claim 24, wherein the propagation delay equals 50% of a time period of a clock signal.

27. The method of claim 24, wherein the selection of propagation delay devices is done though logical addressing.

28. The method of claim 27, wherein registers are used for logical addressing.

29. A method of adjusting a clock signal comprised of:
determining the number of clock signals from a generated clock signal that correspond to a reference frequency;
calculating a propagation delay to create a clock signal;
selecting a plurality of propagation delay devices.

30. The method of claim 29, wherein the calculated propagation delay equals the propagation delay through the selected devices.

31. The method of claim 29, wherein the propagation delay equals 50% of a time period of a clock signal.

32. The method of claim 29, wherein the selection of propagation delay devices is done though logical addressing.

33. The method of claim 32, wherein registers are used for logical addressing.

34. The method of claim 29, wherein the reference frequency is created by a crystal oscillator.

35. A method of adjusting a clock signal comprised of:
determining the number of clock signals from a generated clock signal that corresponds to a reference clock signal;
calculating a propagation delay to create a clock signal;
selecting a plurality of propagation delay devices;
dividing the generated clock signal.

36. The method of claim 35, wherein the calculated propagation delay equals the propagation delay through the selected devices.

37. The method of claim 35, wherein the propagation delay equals 50% of a time period of a clock signal.

38. The method of claim 35, wherein the selection of propagation delay devices is done though logical addressing.

39. The method of claim 38, wherein registers are used for logical addressing.

40. The method of claim 35, wherein the divisor value is calculated by determining the number of clock signals from a generated clock signal that correspond to a reference clock signal

41. The method of claim 35, wherein the reference frequency is created by a crystal oscillator.
